(19) United States
(12) Patent Application Publication
(10) Pub. No.: US 2025/0055484 A1
(43) Pub. Date: Feb. 13, 2025

(54) RECEIVER

(71) Applicant: Novelda AS, Kviteseid (NO)

(72) Inventor: Sumit BAGGA, Kviteseid (NO)

(73) Assignee: Novelda AS, Kviteseid (NO)

(21) Appl. No.: 18/718,302

(22) PCT Filed: Dec. 13, 2022
(86) PCT No.: PCT/EP2022/085616

§ 371 Date: Jun. 10, 2024

(30) Foreign Application Priority Data
Dec. 13, 2021 (GB) 2118017.9

(51) Int. Cl. H04B 1/00; H04B 1/401; H04B 1/44; H04L 5/14

(52) U.S. Cl. CPC H04B 1/0057; H04B 1/401; H04B 1/44; H04L 5/1461

(57) ABSTRACT

A transceiver circuit for transmitting and receiving via a single antenna interface, the transceiver circuit comprising: a transmitter and a receiver, wherein the receiver comprises: a first circuit branch arranged to selectively connect the receiver input to the receiver output; and a second circuit branch arranged to selectively connect the receiver input to a signal ground node. The receiver can be operated to choose which of the two circuit branches to send the signal. In receive mode, the receiver can send the signal over the first circuit branch to the receiver output as normal. In transmit mode, the receiver can send the signal instead over the second circuit branch to ground, thereby dumping the incoming signal, while protecting sensitive processing components downstream of the first circuit branch that are unable to handle the large signal swing of the direct path or reflected transmit pulse.

The invention relates to a receiver front-end, in particular it relates to a radio frequency (RF) front-end for a pulsed or impulse radar such as an ultra-wideband (UWB) radar.

UWB pulsed radars are often used for short range sensing such as proximity, presence and gesture detection, and heart rate and respiration monitoring. In such scenarios, the target to be detected can be very close to the radar, e.g., within a few centimeters, or even a few millimeters. A (strong) reflection from the target (or reflector) will then be received by the radar in a very short space of time after transmission, or even while transmission is still ongoing.

While a reflected signal from such a close target will still be very strong, the receiver architecture is designed for and must be capable of amplifying a reflection from significantly greater distance and therefore of much lower amplitude. The weak reflected signal is boosted by a high gain amplifier, typically a low-noise amplifier (LNA) and may also be accumulated over multiple individual pulses so as to reinforce the reflected signal while averaging out noise. A filter may be placed before the LNA to reject (unwanted) out-of-band signals.

The requirement for a high gain amplifier in the receiver hinders the design of the radar architecture in certain ways. In particular, the transmitter must be high powered to generate pulses with sufficiently large voltage swing so that reflections can be received from a required range. If those high power transmit pulses are fed to the amplifier of the receiver, they can damage the circuitry. Therefore, design is typically limited to either a two-port (2-port) full-duplex design (a transmitter driving a first antenna and a receiver amplifying signal from a second antenna) or a single-port (1-port) half-duplex design in which the receiver and transmitter share an antenna, but the receiver's amplifier is switched OFF or blocked during transmission to protect it from the high power transmit pulse. A 1-port transceiver design is beneficial in terms of form factor as each antenna can take up a lot of physical area. For example, where all the processing can be done on-chip, the antennae make up the majority of the overall device area. Therefore, removing one antenna can almost halve the device area (particularly important for incorporation into small and/or portable devices such as laptops, tablets, mobile telephones or wearable devices or other devices where space is constrained, e.g., the bezel around a display screen). However half-duplex operation restricts near-zero range detection as no reflections can be received (in the receiver's high gain mode) until after the transmitter has finished transmitting and the receive path has been switched back ON.

According to the invention there is provided a transceiver circuit for transmitting and receiving via a single antenna interface, the transceiver circuit comprising:
a transmitter arranged to send a transmit signal to the antenna interface; and
a receiver, having an input and an output, the input arranged to receive a receive signal from the antenna interface;
wherein the receiver comprises:
   a first circuit branch arranged to selectively connect the receiver input to the receiver output; and
   a second circuit branch arranged to selectively connect the receiver input to a signal ground node.

With this architecture, the receiver can be operated to choose which of the two circuit branches to send the signal to. In receive mode, the receiver can send the signal over the first circuit branch to the receiver output as normal. In transmit mode, the receiver can send the signal instead over the second circuit branch to ground (i.e., the signal ground node), thereby dumping the incoming signal, while protecting sensitive processing components downstream of the first circuit branch that are unable to handle the large signal swing of the direct path or reflected transmit pulse (e.g., an analog-to-digital converter (ADC)). It will be appreciated that this operation allows for half-duplex operation, i.e., by receiving while the transmitter is OFF and diverting the receive signal away from signal path while the transmitter is ON. The use of the two circuit branches to control the transmission of the incoming signal is particularly advantageous as it is integral to the receiver circuit and therefore there is no need for a separate, dedicated switch upstream of the receiver. A separate, dedicated switch will add finite resistance, and thus, insertion loss in the ON state, so avoiding that switch is a benefit. In some embodiments the first circuit branch may control the signal transmission (i.e., provide the selectivity) with components that are already a functional part of the receiver architecture, and which therefore do not add any additional signal loss to the receiver.

The architecture described above also allows pseudo full-duplex operation, e.g., by connecting the first and second circuit branches respectively to the receiver output and the (signal) ground, the receiver can achieve a degree of gain control by splitting the incoming signal between the two paths and thereby sufficiently reducing the signal at the output. Further such applications will be discussed below.

The term signal ground node (or more simply ground) here is used to refer to any circuit node that can be used to dissipate the signal. This may be a power rail (e.g., V_{DD} or V_{SS}) but could also be any other ground node of the circuit. The term signal ground node here also includes any AC ground node such as through a capacitor that can pass the signal to ground.

It will be appreciated that the arrangement described here is a direct-RF front end, i.e., the RF signal is received and processed directly without any frequency conversion. In such arrangements the filtering is particularly important to restrict the receive signal to just the signal of interest while excluding out-of-band interferers. In some cases, filtering can be achieved with just the antenna, but for direct-RF arrangements this is usually not sufficient and so a dedicated filter is required. By way of example only, in some direct-RF front ends the filter and amplifier try to realize around 60 dB attenuation out-of-band with a noise figure <5 dB.

In some embodiments, the first circuit branch may be switchable between an ON state and an OFF state, wherein in the ON state the first circuit branch connects the receiver input to the receiver output; and wherein the second circuit branch is switchable between an ON state and an OFF state and wherein in the ON state the second circuit branch connects the receiver input to the signal ground node. The two branches may be selectable by a selector switch that can direct the input signal to either one of the two alternative paths. Alternatively, each branch may be individually switchable, giving rise to the possibility of parallel operation, e.g., for gain control as discussed above.

The OFF state of the first circuit branch may be an open circuit (or effectively an open circuit) which passes zero current. However, in some embodiments the first circuit branch is arranged such that in the OFF state it passes a leakage current from the receiver input to the receiver output. Ordinarily such a leakage current would be contrary to the goal of protecting the downstream circuits. However, leakage current is typically small (the circuit branch may still be considered to be in an OFF state) and therefore does not threaten damage to the downstream components. In fact, the leakage current may be processed to detect a receive signal. This provides a degree of full-duplex operation. Although the leakage current is small and therefore the signal swing is much reduced, the signals that are of particular interest at this point are those that arrive during the transmit pulse. In the case of a radar, these signals are typically from reflections that have been generated from very close to the antenna such that they may be incoming while the transmitter is still transmitting. In half-duplex operation the receiver is completely blind to such signals and so the device cannot detect them at all as the receiver is OFF or blocked. However, reflections from close to the antenna are still of relatively high power compared to those received from much further away and therefore, although the leakage current reduces the received power, such strong reflection signals are still detectable. Therefore, the use of leakage current in this way allows pseudo-full-duplex operation and allows the receiver to still make some use of the “dead” time during the transmit pulse. In a radar, it permits detection close to the antenna, which is of great benefit in many devices, e.g., for gesture detection or for monitoring vital signs with wearables.

The amount of leakage that is allowed in the OFF state of the first circuit branch may vary according to the design and the components used. The amount of leakage permissible may also vary depending on the strength of the transmitter and on the downstream components and to what extent they need to be protected. The skilled person will understand how to select appropriate components in order to design the circuit branches for an appropriate amount of leakage according to the application. However, by way of example, in some embodiments, in the OFF state the first circuit branch has an insertion loss of up to 20 dB. In other embodiments the insertion loss may be up to 15 dB or up to 10 dB. It will be appreciated that allowing more current to leak through allows for easier processing of any reflection signal in the leaked signal, providing that the unwanted transmit signal is still sufficiently attenuated.

The first circuit branch may comprise a first switchable element, wherein the first switchable element is arranged to switch the first circuit branch between the ON state and the OFF state. The first switchable element may be a controllable switch, e.g., a digitally controllable switch. Any type of switch may be used, although for high-speed implementations, electronic switches are preferred. In some embodiments the first switchable element may be a transistor. In particular, the transistor may be a field effect transistor (FET).

In some preferred embodiments, the first switchable element is a low-threshold voltage transistor, optionally an ultra-low threshold voltage transistor, optionally an extreme-low threshold voltage transistor. Such transistors have the benefits of fast operation, but more importantly, due to the low-threshold voltage, such transistors are leaky in the OFF state, and thus provide the desired current leakage through the first circuit branch. Low-threshold voltage transistors (referred to as LVT) have a lower threshold voltage for activation than regular or standard threshold voltage transistors (which may be referred to as RVT or SVT). Ultra-low threshold voltage (ULVT) transistors have a lower threshold voltage then LVTs and extreme-low threshold voltage (ELVT) transistors have a lower threshold voltage than ULVTs. As the threshold voltage decreases, the leakage increases such that ULVTs have a higher leakage than ELVTs which in turn have a higher leakage than LVTs. RVT or SVT transistors do not have appreciable leakage in most applications. The choice of which type of transistor to use will depend on the circuit design and the amount of leakage desired, i.e., on the amount of signal that it is desired to let through when the first circuit branch is in the OFF state.

The first circuit branch preferably comprises a first buffer element in series with the first switchable element. The first buffer element serves to buffer the signal through the first circuit branch. In normal operation, this provides high output impedance (as seen from the load) and reverse isolation, i.e., to isolate the load connected to the output from the input and guarantee unconditional stability. The first buffer element may be a non-switchable element configured to be in an always-ON configuration. The isolation provided by the first buffer element prevents any changes in load from impacting any impedance matching upstream (i.e., closer to the antenna). In addition, the load conditions (e.g., frequency selectivity) remain unaffected. This has the benefit that the frequency response of the receiver remains the same regardless of operating mode. Even when the only signal through the receiver is via leakage through the first circuit branch, the frequency response retains the same shape, just at a lower level. This facilitates subsequent processing of the signal. It will be appreciated that when the first switchable element is a transistor it can also provide amplification to the signal in addition to providing its function of switching off the circuit branch. Thus, the first switchable element may be an integral part of the amplifier. Equally, the first buffer element could be made to be switchable as well, but this is not necessary given the presence of the first switchable element. The first buffer element may also be a switchable element (such as a transistor) configured so as to be in an always-ON configuration. The first buffer element may be a unity gain buffer, or it may be a buffer amplifier to provide additional gain if desired.

The first buffer element may be connected between the first switchable element and the receiver output.

The first buffer element may be a single stage or a cascade of stages. For a single stage, it may comprise a field effect transistor (FET). It is preferably a low-threshold voltage transistor, optionally an ultra-low threshold voltage transistor, optionally an extreme-low threshold voltage transistor.

In a particularly preferred arrangement, the first switchable element and the first buffer element each comprise transistors in a common-gate (CG) arrangement (i.e., current buffers). Thus, the first circuit branch comprises a common-gate configured transistor as the first switchable element, with its drain connected to the source of a common-gate configured transistor as the first buffer element. The drain of the first buffer element can also be directly connected to the receiver output (e.g., the drain of the first buffer element may be the output node of the receiver). The first buffer element provides the reverse isolation while the first switchable element provides the ON/OFF control of the first circuit branch as well as acting as a current buffer (with low input impedance and high output impedance). The first buffer element (e.g., a non-switching CG-stage) buffers signal from the first switchable element to the load.

The second circuit branch may be constructed in the same way as the first circuit branch.

The second circuit branch may be arranged such that in the OFF state it passes a leakage current from the receiver input to the signal ground node. In some embodiments, in the OFF state the second circuit branch has an insertion loss of up to 20 dB. In other embodiments the insertion loss may be up to 15 dB or up to 10 dB. Ideally, the insertion loss of the second circuit branch is the same as for the first circuit branch.

The second circuit branch could alternatively be a non-leaky arrangement as there is no need for the second circuit branch to bleed current away from the receiver output when operating in receive mode (i.e., when the transmitter is not in use). However, there are advantages to having the two branches be identical so that any upstream components see exactly the same impedance and biasing conditions regardless of which branch is connected. This maintains impedance matching to the antenna in transmit and receive modes, and thus ensures minimal mismatch loss so as to maximize signal transmission and reception. It will also be appreciated that leakage in the second circuit branch is slightly detrimental to the signal transmission to the receiver output in the receive mode as the second circuit branch will always allow a small fraction of the input power to dissipate to ground. However, this loss is acceptable given the benefits of impedance matching as discussed above.

Similarly, to the first branch, the second circuit branch may comprise a second switchable element, wherein the second switchable element is arranged to switch the second circuit branch between the ON state and the OFF state. The second switchable element may be a low-threshold voltage transistor, optionally an ultra-low threshold voltage transistor, optionally an extreme-low threshold voltage transistor. The second switchable element may be identical to the first switchable element. Identical here means to have the same characteristics so that the two circuit branches have the same effect on the circuit when they are used as alternatives. In practice, this means that the switches may have the same physical dimensions. They may be made from the same material with the same doping. They may be transistors with the same leakage characteristics. They may have the same threshold voltage.

The second circuit branch may comprise a second buffer element in series with the second switchable element. The second buffer element may be connected between the second switchable element and the signal ground node. The second buffer element may be a low-threshold voltage transistor, optionally an ultra-low threshold voltage transistor, optionally an extreme-low threshold voltage transistor. The second switchable element and the second buffer element may each comprise transistors in a common-gate arrangement. The second buffer element may be a unity gain buffer, or it may be a buffer amplifier to provide additional gain if desired. As above, the second buffer element may be identical to the first buffer element so as to provide the same characteristics when the second circuit branch is used as an alternative to the first circuit branch.

The transceiver circuit can be operated in different modes by selecting either or both of the first and second circuit branches. In some embodiments the transceiver circuit further comprises a controller; wherein the controller is arranged to operate in at least a transmit mode and a receive mode; wherein in the receive mode, the controller controls the first circuit branch to connect the receiver input to the receiver output; and wherein in the transmit mode, the controller controls the second circuit branch to connect the receiver input to the signal ground node. In the transmit mode, the transmitter is active and provides a strong signal at the receiver input. In order to prevent damage to downstream components, the second circuit branch is controlled to divert the signal (or at least the majority of it) in the receiver to the signal ground node. In the receive mode, the first circuit branch is controlled to pass the signal (or at least the majority of it) in the receiver to the receiver output for onwards processing. In this mode, the transmitter is not active and so the only signal present at the receiver input is the (wanted) received small-signal from the antenna. In this mode, maximum amplification is desired for said signal.

Preferably in the receive mode, the controller controls the second circuit branch to disconnect the receiver input from the signal ground node; and in the transmit mode, the controller controls the first circuit branch to disconnect the receiver input from the receiver output. Thus, the first and second circuit branches are used in the alternative. The signal from the receiver input is directed either to the second circuit branch and to ground, or it is directed to the first circuit branch and to the receiver output. It will be appreciated that in embodiments in which at least one of the circuit branches is leaky, most of the signal will be directed down one of the alternative paths, while a small fraction will still pass up the non-selected path.

As discussed above, for maximum signal transmission and reception, it is necessary to ensure an impedance match with the antenna. One particularly convenient way to do this is with an impedance matching amplifier stage as the first amplifier stage of the receiver. Therefore, in some embodiments the receiver comprises an impedance matching amplifier arranged to receive the receive signal from the antenna interface and arranged to output an amplified signal to the first and/or second circuit branches. The impedance matching amplifier provides transconductance gain (i.e., voltage to current conversion). The impedance matching amplifier can be designed so that the correct impedance match is one of its characteristics, while still providing gain to the input signal. In preferred embodiments there is no explicit switch upstream of the impedance matching amplifier. No such switch is required as the selectivity that allows for half duplex or pseudo-full-duplex operation is downstream of the impedance matching amplifier. The impedance matching amplifier may comprise a transistor or multiple transistors arranged in a common-gate and/or a common-source arrangement. One way to achieve this is with a field effect transistor arranged in either common-gate or common-source configuration, with the windings of a trifilar transformer coupling the signal between at least the gate and the source, while ensuring that there is only coupling between two of its windings (which ensures stability and/or maximum gain). This arrangement allows additional characteristics, such as the turns ratio of the windings and the coupling coefficient to impact on the impedance matching. Therefore, the amplifier can be designed for both gain and impedance matching. While a trifilar arrangement is particularly convenient and area-efficient, a similar effect can also be achieved with two transformers (bifilars).

It will be appreciated that this amplifier is necessarily provided upstream of (i.e., closer to the antenna than) the first and second circuit branches, and therefore, it will see the full power of the transmit signal when the transceiver is in transmit mode. Thus, this transistor can be designed to be sufficiently robust (e.g., with thick-oxide) to handle the large-signal swing from the transmitter. It will be appreciated that as this is the first amplifier in the receiver, it has not yet amplified the transmitter signal and so is the least problematic part of the receiver circuit. The signal downstream of this amplifier has been amplified, and thus, becomes a reliability issue (i.e., risks damaging downstream components). This arrangement is of particular benefit in pulsed transceivers, e.g., pulsed, or impulse radars. In such systems (as opposed to continuous wave transceivers) the transmitter is only active for short periods of time (to transmit a pulse) before going inactive for long periods of time (the rest of the pulse repetition period). Thus, the power that must be withstood by the amplifier is short and transient and thus a sufficiently robust transistor can be incorporated without great expense. The arrangement is especially beneficial in low-power transceivers, e.g., UWB transceivers as the transmit power restrictions in the UWB band also facilitate the use of an amplifier element that is fully exposed to the full transmit power of the transmitter.

Note that the single common-gate or common-source transistor mentioned above can be replaced by multiple transistors acting as a transconductance stage. For example, the gain stage could be a circuit (commonly referred to as a Darlington pair) comprising two transistors with the source of the first transistor connected to the gate of the second transistor, and the drains of the two transistors connected. Another example being a common-source transistor and a common-gate transistor in parallel arrangement with the source of the common-gate transistor connected to the gate of the common-source transistor and with the drains of the two transistors connected via an ‘inversion’. Other multiple transistor arrangements are also possible.

In some examples, the impedance matching amplifier comprises a field effect transistor and wherein the impedance matching amplifier further comprises a transformer coupling the signal between the gate and the source of the field effect transistor. This coupling provides an additional gain mechanism by applying the signal at the gate to the source or vice-versa. By arranging the transformer in an inverting relationship, the gate-source voltage is increased, thereby increasing the gain of the transistor.

In some examples, the field effect transistor is in common-source arrangement and the impedance matching amplifier comprises a transformer arranged to increase the amplitude of the signal at the gate of the field effect transistor.

In such examples, the transformer may be a trifilar transformer with a primary winding connected to the source, a secondary winding connected between the gate and signal ground and a tertiary winding connected between the secondary winding and the gate, wherein the primary winding and the secondary winding are coupled in inverting relationship, wherein the secondary winding and the tertiary winding are coupled to increase voltage at the gate, and wherein there is substantially no coupling between the primary winding and the tertiary winding. With this arrangement, the coupling between the primary and secondary windings increases the gate-source voltage as discussed above, thereby providing one gain mechanism. At the same time, the coupling between the secondary and tertiary windings further increases the gate voltage (and therefore also the gate-source voltage), thereby providing an additional gain mechanism. At the same time, as the input impedance of the arrangement depends upon both the transconductance of the transistor and the turns ratios of the transformer, it is possible to achieve good impedance matching via a well-defined input impedance as well as high gain. More details of this type of arrangement can be found in WO2018/033743, the entire contents of which are incorporated herein by reference. A similar effect may be achieved by using two bifilar transformers instead of a trifilar. This may be achieved with one bifilar providing coupling between the source and the gate (equivalent to the primary and secondary of the trifilar), and one bifilar providing coupling to increase the gate voltage (equivalent to the secondary and tertiary of the trifilar).

In other examples, the field effect transistor may be in common-gate arrangement and the impedance matching amplifier comprises a transformer coupling the signal between the source and the drain of the field effect transistor. This source-drain coupling provides an additional gain mechanism by applying the signal (current) sensed at the drain back to the source. By arranging the transformer in a non-inverting relationship, the drain-source current is increased, thereby increasing the gain of the transistor.

In such examples, the transformer may be a trifilar transformer with a primary winding connected to the source, a secondary winding connected to the gate and a tertiary winding connected to the drain, wherein the primary winding and the secondary winding are coupled in an inverting relationship and wherein the primary winding and the tertiary winding are coupled in non-inverting relationship, and wherein there is substantially no coupling between the secondary winding and the tertiary winding. With this arrangement, the coupling between the primary and secondary windings increases the gate-source voltage as discussed above, thereby providing one gain mechanism. At the same time, the coupling between the primary and tertiary windings increases the drain-source current, thereby providing an additional gain mechanism. At the same time, as the input impedance of the arrangement depends upon both the transconductance of the transistor and the turns ratios of the transformer, it is possible to achieve good impedance matching via a well-defined input impedance as well as high gain. More details of this type of arrangement can be found in WO2019/086853, the entire contents of which are incorporated herein by reference. A similar effect may be achieved by using two bifilar transformers instead of a trifilar. This may be achieved with one bifilar providing coupling between the gate and the source (equivalent to the primary and secondary of the trifilar), and one bifilar providing coupling between the source and the drain (equivalent to the primary and tertiary of the trifilar).

The transceiver circuit may comprise a controller; wherein the controller is arranged to operate in a gain control receive mode; wherein in the gain control receive mode, the controller controls the first circuit branch to connect the receiver input to the receiver output, and the controller controls the second branch to connect the receiver input to the signal ground node. It will be appreciated that this controller may be the same controller as the one discussed above, or it may be a separate controller. The exact set up does not matter so long as the appropriate controls can be carried out.

The receiver may further comprise: a third circuit branch arranged to selectively connect the receiver input to a signal ground node. It will be appreciated that the receiver may further comprise a fourth, fifth, sixth, etc. further circuit branches each arranged to selectively connect the receiver input to ground. It will also be appreciated that these may all connect to the same ground node, but this is not necessary as each can connect to a separate ground node if that is more convenient. The provision of these multiple circuit branches parallel to the main receive path (the one to the receiver output) is to provide a degree of gain control during receive mode. During transmit mode, any one (or multiple) of these paths may be used to divert the signal away from the load to ground, thereby protecting the downstream circuitry (and the main receiver path may leak current as discussed above). However, in the receive mode, the receiver may control the degree of gain in the receiver by engaging one or more of these second, third, fourth, etc. paths to share the current with the main receive path (first circuit branch). The more paths that are engaged, the more current is taken away from the main receive path, and therefore, the lower the gain provided by the receiver. Gain may be controlled depending on the signal strength received at the antenna, which may vary during use depending on the type of transmissions that are being received, and from how far. In a radar, reflections may be from a strong reflector (reflects almost all of the incident transmit pulse) or a weak reflector (absorbs or scatters some of the transmit pulse while only reflecting a portion back to the receiver). Additionally, the distance of the reflector from the radar affects the strength of the receive pulse. Therefore, the amount of gain required may vary during operation and may need to be adapted during use. The second and third circuit branches (and further circuit branches if present) may have different current drawing strengths. This allows different levels of gain control to be achieved by selecting a single branch of the appropriate strength. Of course, multiple branches of different strengths can also be used to increase the current draw further. If desired, the multiple branches other than the first may have a binary arrangement of strengths (1×, 2×, 4×, etc.) so that any strength may be achieved through appropriate combination. It will be appreciated that all branches may be controlled by a controller which may be the same as or different from the previous controllers discussed above.

The invention extends to a transceiver comprising: a transmitter circuit, an antenna, and a transceiver circuit as described above. The transceiver circuit may optionally include any number of the preferred and optional features that are discussed above.

The invention is particularly applicable to pulsed transmissions where there is a short, high energy transmit pulse during which the receiver must be protected from the high energy, and then a long gap between pulses in which reception can be at full amplification. Therefore, in some embodiments the transmitter circuit may comprises an impulse or pulse generator.

Some particularly preferred embodiments are a pulsed radar comprising a transceiver as discussed above, optionally including any number of the preferred and optional features. A pulsed radar benefits particularly from these arrangements as the transmit pulse can be reflected from close reflectors such that the received signal may arrive before the transmitter has stopped transmitting. In addition, as noted above, the pulsed operation means that the transmit power to which the impedance matching amplifier is exposed is low and short-lived. In some preferred embodiments, the pulsed radar is a UWB radar. The arrangements described above can provide a convenient half-duplex operation, or in particularly advantageous embodiments can provide a degree of full-duplex operation by passing a receive signal at lower or much lower gain than normal-receive-gain. It will be appreciated that the lower-than-normal-receive-gain may in fact be a signal loss (i.e., an attenuated signal), but not a total loss such that some signal is still passed through the receiver for processing. This kind of pseudo-full-duplex with a single antenna is highly beneficial in certain small form factor devices where physical space is constrained but short distance detection is required, e.g., for presence detection or gesture detection proximate a small or hand-held device or for vital sign monitoring with wearables.

According to another aspect, the invention provides a method of duplex operation of a transceiver circuit via a single antenna interface, wherein the transceiver circuit comprises:
a transmitter arranged to send a transmit signal to the antenna interface; and
a receiver, having an input and an output, the input arranged to receive a receive signal from the antenna interface;
wherein the receiver comprises:
   a first circuit branch arranged to selectively connect the receiver input to the receiver output; and
   a second circuit branch arranged to selectively connect the receiver input to a signal ground node;
wherein the method comprises:
while the transmitter is transmitting, operating the second circuit branch to connect the receiver input to the signal ground node and operating the first circuit branch to operate in a leakage mode in which the receiver input is disconnected from the receiver output apart from a leakage current that still passes from the receiver input to the receiver output.

In some embodiments the method may further comprise: while the transmitter is not transmitting, operating the second circuit branch to disconnect the receiver input from the signal ground node and operating the first circuit branch to connect the receiver input to the receiver output.

It will be appreciated that all of the other features described above with respect to the apparatus apply equally to the method of operation. Therefore, each and every preferred or optional feature discussed above may also be applied to the method.

It will be appreciated that all of the preferred and optional features discussed above may also be applied correspondingly to the method of operation.

Certain preferred embodiments of the invention will now be described, by way of example only, and with reference to the accompanying drawings in which:

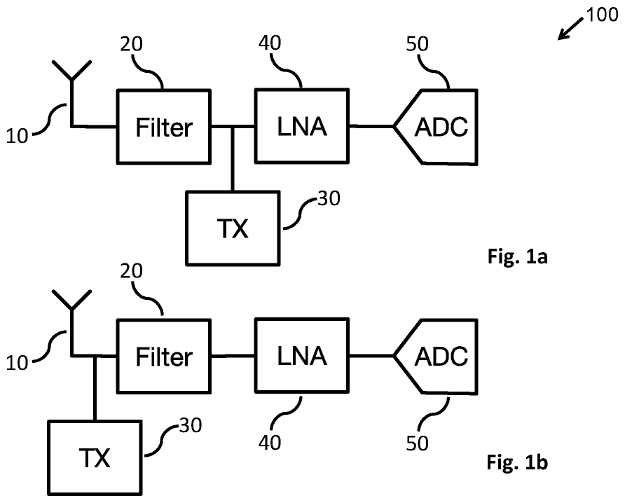

FIGS. 1a and 1b show two direct RF front-end topologies;

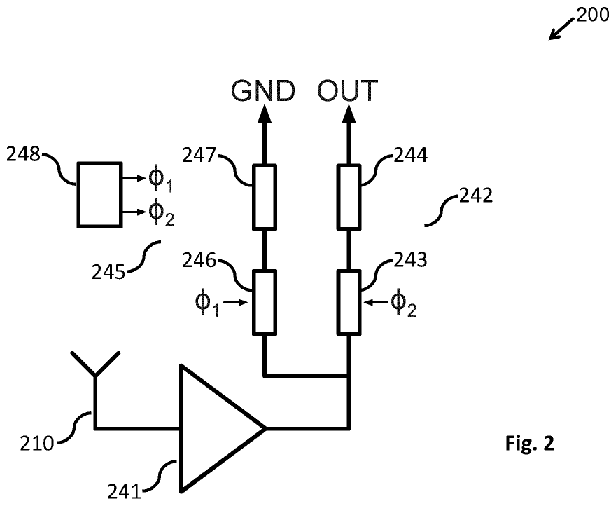

FIG. 2 shows a receiver with two parallel circuit branches;

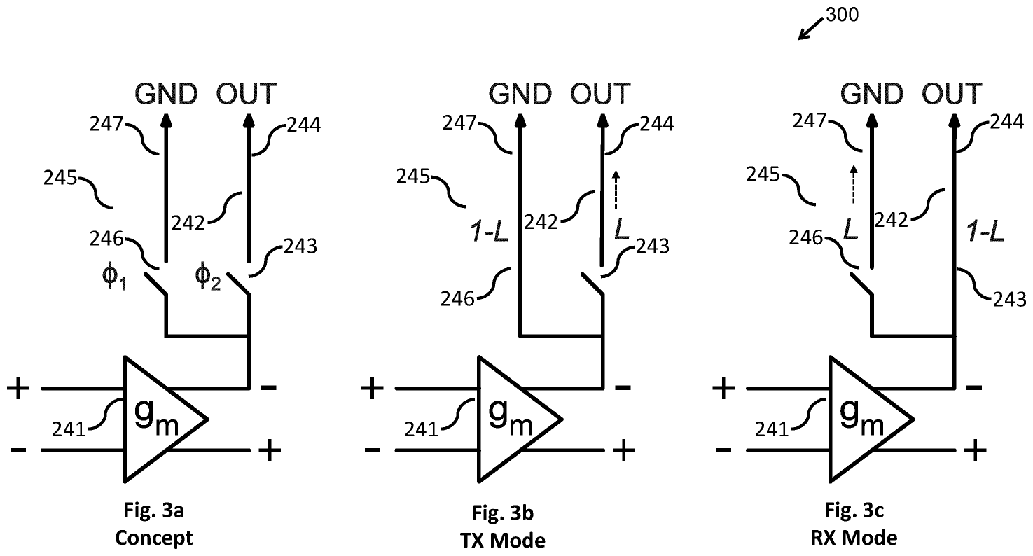

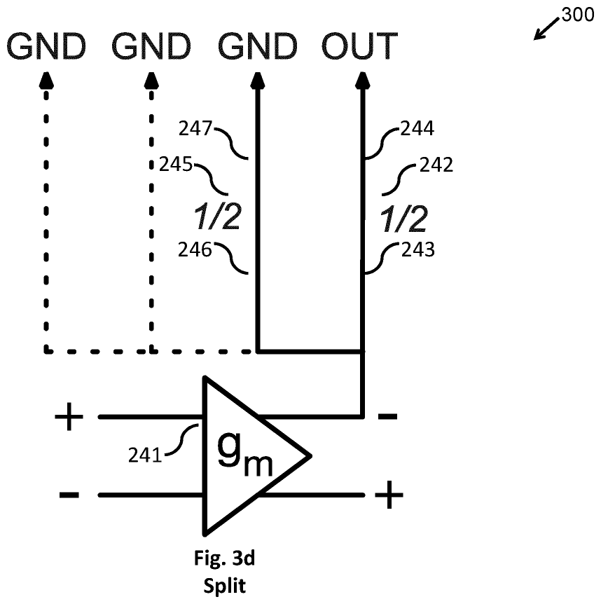

FIG. 3a-d show schematically how two circuit branches can be used in different operating modes;

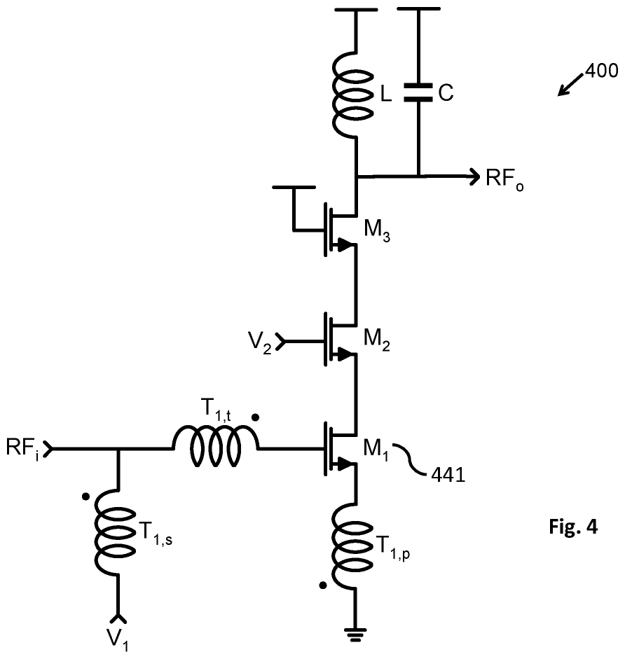

FIG. 4 shows a prior art low-noise amplifier arrangement with a single branch;

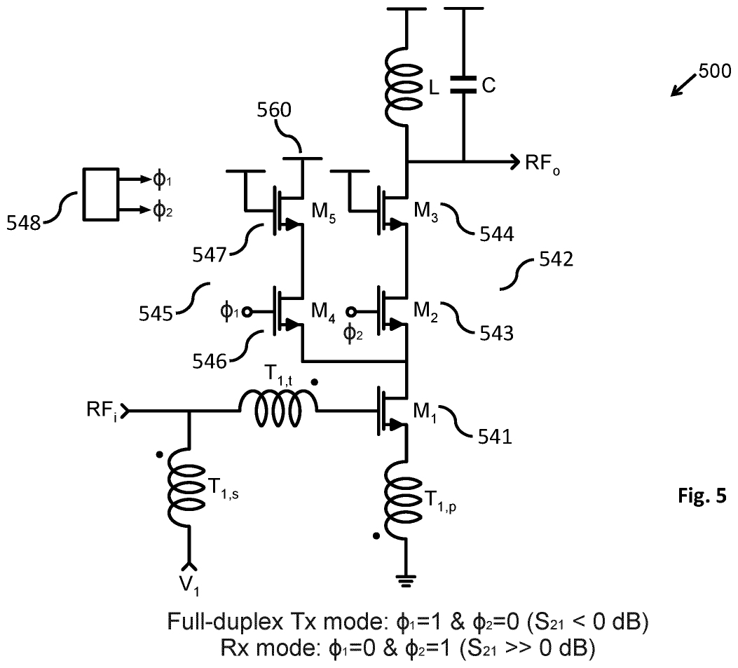

FIG. 5 shows a first embodiment of a duplex receiver circuit;

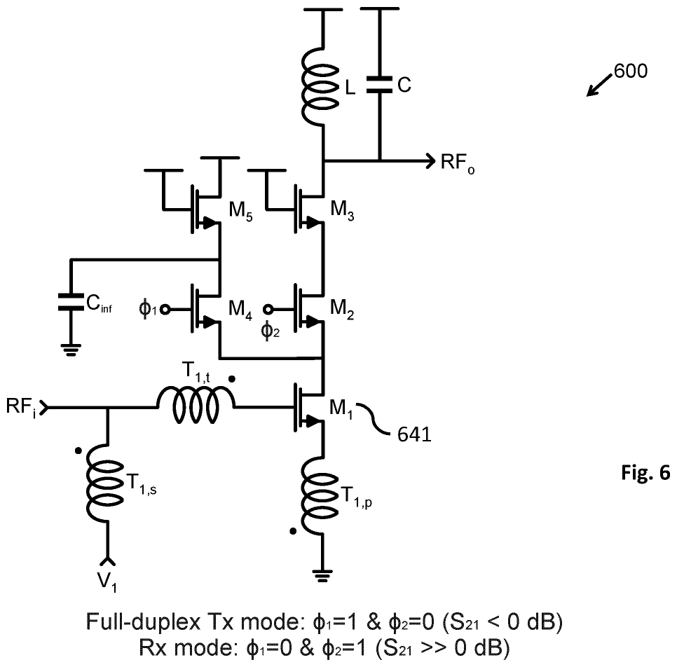

FIG. 6 shows a second embodiments of a duplex receiver circuit;

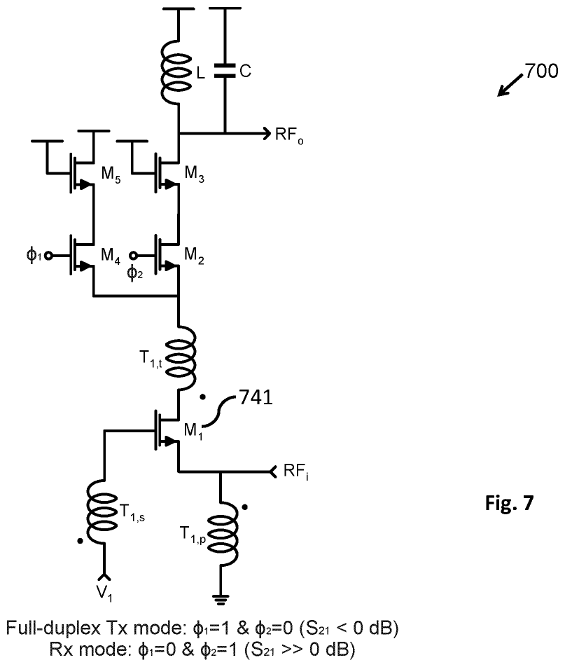

FIG. 7 shows a third embodiment of a duplex receiver circuit;

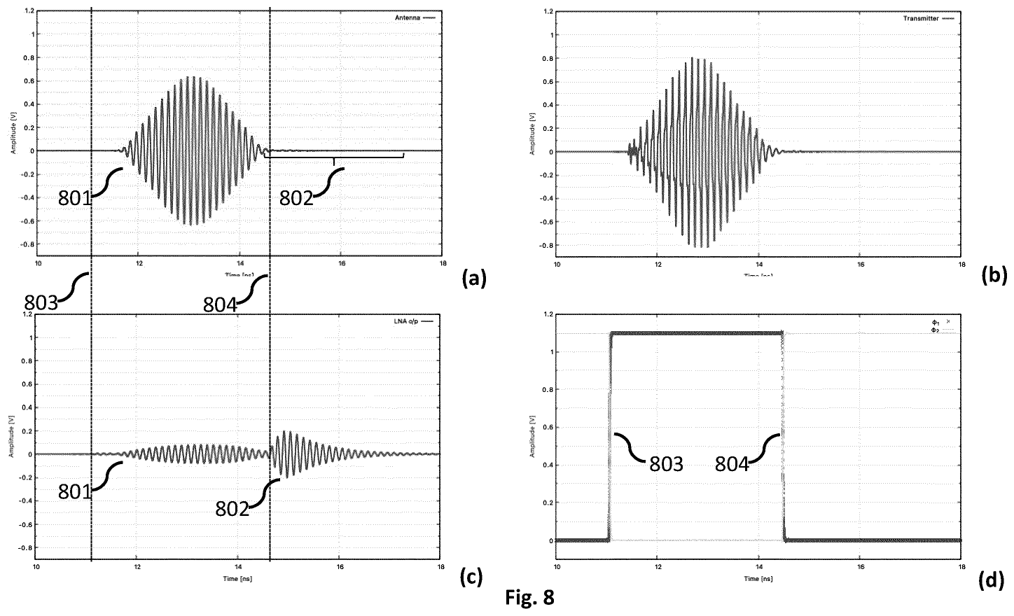

FIG. 8 a) shows signal at the antenna, b) signal at the transmitter, c) leakage signal at receiver output, and d) control signals;

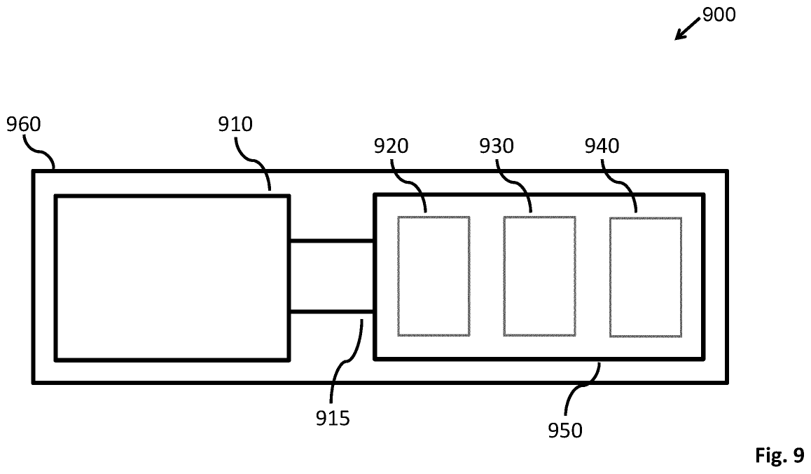

FIG. 9 shows schematically the components of a pulsed radar module.

FIGS. 1a and 1b show two different general arrangements for a direct-RF radio frequency (RF) transceiver front-end 100. Both of these arrangements are single-port devices, i.e., they have a single antenna 10 that is used for both transmission and reception. Each front-end 100 has an antenna 10, a filter 20, a low-noise amplifier (LNA) 40, an analog-to-digital converter (ADC) 50 and a transmitter 30. As these are direct-RF front ends, there are no mixers for up/down conversion. In FIG. 1a, the transmitter 30 is connected to a node between the filter 20 and the LNA 40 while in FIG. 1b it is connected between the antenna 10 and the filter 20. The difference between these arrangements is in whether the output from the transmitter 30 gets filtered by the filter 20. Both of these arrangements are viable for the embodiments described below. Each has advantages. The advantage of the arrangement in FIG. 1a is that the transmitter 30 signal is filtered by the filter 20. This helps to ensure that the transceiver output meets frequency transmission requirements. For example, for an UWB (ultra-wide band) transmitter, there is a spectrum mask that must be adhered to. Applying the filter 20 to the output of the transmitter 30 helps to filter out frequencies that would violate the spectrum mask. However, the filter 20 also results in a certain degree of attenuation. Ideally the filter 20 is transparent to the signals of interest (both outgoing and incoming), but in reality, there is always an insertion loss associated with any passive filter 20. Therefore, placement of the filter 20 as in FIG. 1a means that the transmitter 30 must be higher powered in order to make optimum use of the available spectrum mask (or alternatively, for a given power, the range of the device is compromised by the insertion loss in the filter 20). The full power of the transmitter 30 is also then seen by the receiver parts of the circuit, i.e., the LNA 40 and ADC 50. A higher powered transmitter 30 can risk damaging these components and therefore placement of the transmitter 30 as in FIG. 1a requires either limiting the power of the transmitter 30 or taking greater precautions to protect the LNA 40 and ADC 50. With the arrangement of FIG. 1b the full power of the transmitter 30 is available to the antenna 10 without loss, but it is unfiltered, hence potentially compromising the spectrum efficiency of the transmitter 30 or requiring additional filtering to be built into the transmitter 30 and/or antenna 10 at extra cost and complexity. However, with this arrangement the output of the transmitter 30 that is seen by the LNA 40 and the ADC 50 is first filtered and thus attenuated by the filter 20, thereby protecting those components somewhat from the high power of the transmitter 30. Such protection is still not generally enough to prevent damage to the LNA 40 and/or ADC 50 from the high signal swing of the transmitter 30, so additional protective measures are still normally required.

FIG. 2 shows a general layout of a transceiver 200 according to certain embodiments of the invention. The filter 20 and transmitter 30 are not shown here for simplicity, but they may be located between the antenna 210 and the impedance matching amplifier 241 according to either of the arrangements of FIGS. 1a and 1b.

The impedance matching amplifier 241 is designed to receive the received signal from the antenna 210 and to provide an input impedance that matches the impedance of the antenna 210 so that the signal transmission is maximized (signal loss is minimized). For the very small receive signals that may be expected from an impulse radar, it is generally important to maximize the signal transmission throughout the receiver. The impedance matching amplifier 241 achieves this impedance matching as part of its design which avoids the need for other impedance matching units and thereby maintains efficiency of signal transmission. However, as the impedance matching is achieved by the impedance matching amplifier 241, it is therefore also important to ensure that the loading (biasing conditions) of the impedance matching amplifier 241 does not change (or at least not significantly) during use as changes in loading conditions may change the impedance matching characteristics of the amplifier 241, which could in turn detrimentally affect performance.

The impedance matching amplifier 241 amplifies the incoming signal from the antenna 210 (and the filter which is not shown).

Downstream of the impedance matching amplifier 241 (i.e., on the opposite side from the antenna 210), the amplified output signal from the impedance matching amplifier 241 has two possible paths to take. The first path is a first circuit branch 242 which comprises a first switching element 243 and a first buffer element 244.

The second path is a second circuit branch 245 which comprises a second switching element 246 and a second buffer element 247.

The first switching element 243 is controllable by a first switching signal ϕ₂ and the second switching element 246 is controllable by a second switching signal ϕ₁. Each of these switching elements 243, 246 can be used to engage or disengage the corresponding circuit branch 242, 245. That is the first switching element 243 can selectively connect or disconnect the output of the amplifier 241 to the load (OUT) and the second switching element 246 can selectively connect or disconnect the output of the amplifier 241 to ground (GND). As has been noted elsewhere in this document, the ground here can be any signal ground to which the signal through the second circuit branch 245 can be dissipated. This may be a positive or negative voltage rail, an AC ground, or any other ground connection of the circuit.

The first buffer element 244 and the second buffer element 247 buffer the signal on their respective branch respectively from the load and ground connections. In particular, the first buffer element 244 provides a high output impedance that isolates the load from the impedance matching amplifier 241. As noted above, this is important in order to isolate the load and prevent the load from influencing the impedance matching characteristics of the amplifier 241. This in turn ensures that changes in the load do not negatively impact the path from the antenna 210 to the load (i.e., do not introduce losses that could hinder detection). Similarly, the second buffer element 247 isolates the amplifier 241 from the ground when the second circuit branch 245 is connected (via the second switching element 246). Although there are not the same load variations at the ground connection of the second circuit branch 245 as there are at the load connection of the first circuit branch 242, the second buffer element 247 ensures that the amplifier 241 experiences the same loading conditions regardless of which circuit path(s) (first circuit branch 242, second circuit branch 245 or both) is/are connected. Therefore, the impedance matching amplifier 241 always experiences stable conditions and therefore retains its impedance match accurately throughout operation, even as the first and second circuit branches 242, 245 are switched ON and OFF.

Operation of the transceiver 200 will be described with reference to FIGS. 3a to 3d. In FIGS. 3a-d, the amplifier 241 is shown as a differential amplifier with both positive and negative inputs and positive and negative outputs. The first and second circuit branches 242, 245 are shown attached to the negative amplifier output. For simplicity, the downstream connections of the positive amplifier output are not shown, but it may be understood that they are the same as for the negative amplifier output.

A controller 248 is also shown in FIG. 2 which generates the control signals ϕ₁ and ϕ₂ in order to control operation of the transceiver 200 by switching ON/OFF the switching elements 243, 246.

FIG. 3a is similar to FIG. 2 and shows the general operating principle. The first switching element 243 and the second switching element 246 are illustrated as simple switches (both shown open for illustrative purposes). The first buffer element 244 and the second buffer element 247 are illustrated here simply as connections that pass the current. In practice, as shown in the following embodiments, the buffer elements 244, 247 may be implemented with switchable components (such as transistors), but any arrangement that provides the required buffering may be used. The amplifier 241 is labelled “gₘ” to indicate that it is a transconductance amplifier taking a voltage input and generating a current output. However, the principles of operation discussed here are not dependent on the amplifier type which may be any suitable amplifier circuit. In particular, the amplifier 241 may be an impedance matching amplifier such as that of FIG. 2.

The first circuit branch 242 can be switched to an ON state in which the load is connected to the amplifier 241, or it can be switched to an OFF state in which the load is disconnected from the amplifier 241. This ON/OFF state is selected by opening or closing the first switching element 243. The switching element 243 is an electrically controllable switching element 243, controlled by the signal ϕ₂. The second circuit branch 245 can be switched to an ON state in which the signal ground node is connected to the amplifier 241, or it can be switched to an OFF state in which the signal ground node is disconnected from the amplifier 241. This ON/OFF state is selected by opening or closing the second switching element 246. The switching element 246 is an electrically controllable switching element 246, controlled by the signal ϕ₁.

Each of the circuit branches 242, 245 is separately controllable so that it is possible to have both circuit branches ON, both circuit branches OFF or either branch ON with the other branch OFF. Switching both circuit branches 242, 245 OFF will completely switch the receiver off so that nothing is received. This will affect the impedance matching of amplifier 241. In order to maintain the impedance matching characteristics of amplifier 241, at least one of the circuit branches 242, 245 should be switched ON.

When the first circuit branch 242 is OFF and the second circuit branch 245 is ON, the current from amplifier 241 is directed to the signal ground node (labelled “GND” in FIGS. 3a-3d) through second switching element 246 and second buffer element 247. First switching element 243 is controlled to be open, thereby preventing current from passing to the load. This is illustrated in FIG. 3b “TX Mode” as this is the mode for blocking the receiver while the transmitter is active (i.e., generating a strong signal for pulse transmission). During this period, the downstream components (e.g., ADC, etc.) need to be protected from the strong transmit signal.

When the first circuit branch 242 is ON and the second circuit branch 245 is OFF, the current from amplifier 241 is directed to the load through first switching element 243 and first buffer element 244. Second switching element 246 is controlled to be open, thereby preventing current from passing to ground. This is illustrated in FIG. 3c “RX Mode” as this is the mode for receiving and processing signal from the antenna with maximum gain and maximum signal transmission to the downstream components (e.g., ADC, etc.).

FIGS. 3b and 3c also illustrate the operation of the first and second circuit branches 242, 245 when the first switching element 243 and the second switching element 246 are designed to be leaky, i.e., they cannot be switched fully OFF, but instead will still pass a certain proportion of current when the corresponding control signal ϕ₁, ϕ₂ closes the switching element 246, 243, respectively. FIGS. 3b and 3c illustrate this via the dashed arrow displayed alongside the open (OFF) circuit branch (first circuit branch 242 in FIG. 3b and second circuit branch 245 in FIG. 3c). The current split between the two circuit branches 242, 245 is also illustrated with the leakage current “L” being indicated as passing through the leaky (OFF) circuit branch and the remainder “1-L” being indicated as passing through the ON circuit branch. Thus, in FIG. 3b, leakage current L passes through the first circuit branch 242 to the load (OUT), even though first switching element 243 is open, thereby putting the first circuit branch 242 in the OFF state. The remaining current 1-L is diverted to the signal ground node (GND) through the second circuit branch 245 which is in the ON state. Similarly, in FIG. 3c, leakage current L passes through the second circuit branch 245 to the signal ground node (GND), even though second switching element 246 is open, thereby putting the second circuit branch 245 in the OFF state. The remaining current 1-L passes to the load through the first circuit branch 242 which is in the ON state, for signal processing and detection.

The leakage current loss L in the receive mode (FIG. 3c) slightly depletes the signal transmitted to the load, reducing the sensitivity of the receiver very slightly. However, the corresponding benefit is that in the transmit mode (FIG. 3b), the leakage current through the first circuit branch 242 to the load is greatly reduced in amplitude such that the strong transmit pulse does not damage the processing circuitry, while still allowing processing to take place. Thus, any receive signal present during the transmit process (e.g., from a very close reflector) can still be detected during the transmit process. Thus, the transceiver 200 can operate in a pseudo-full-duplex mode even though it is a single-port device, i.e., with a single antenna for both signal transmission and reception.

FIG. 3d shows another mode of operation in which both the first and second circuit branches 242, 245 are in the ON state. This splits the current between the two branches so that half goes to the load and half goes to ground. This arrangement provides a degree of gain control which may be useful when a strong receive pulse is present and the amplification by amplifier 241 is too much (but not so much as to be a danger as in the transmit mode). By diverting half the current to ground, the gain is reduced by half so that the receive signal passed to the downstream circuitry is lower and easier to process. FIG. 3d also shows in dashed lines the possibility to include further circuit branches (third, fourth, etc.) that can be switched on in parallel so as to split the current in a ratio other than 50:50. For example, three equal branches will split the current one third to the load and two thirds to ground (as both the second and third branches divert current to ground). Equally, the second, third, fourth, etc. branches that divert to ground can have different current drawing strengths so that they can be combined in different combinations to achieve different current splits and thus different levels of gain control. As an example, a binary system can be used with a second branch of strength 1, a third branch of strength 2 (draws twice as much current as the second branch) and a fourth branch of strength 4 (draws four times as much current as the second branch). Such a system can produce eight different levels of current draw from 0 through to 7 times the current drawing strength of the second branch. It will of course be appreciated that other schemes may be used, and further branches may be added.

FIG. 4 shows the basic construction of a common-source amplifier 400 with a trifilar transformer for high gain and impedance matching. For maximum gain, the primary winding Tip is coupled to the secondary winding T_{1,s} and the secondary winding T_{1,s} is coupled to the tertiary winding T_{1,t}. However, the tertiary winding T_{1,t} is not coupled to the primary winding Tip so as to ensure maximum gain of the amplifier. The turns ratios of T_{1,p} to T_{1,s} and T_{1,s} to Tit affect the impedance matching of the amplifier and therefore both the gain and the impedance matching can be set as desired. The three windings T_{1,p}, T_{1,s} and T_{1,t}, together with the field effect transistor M₁ in common-source arrangement form the impedance matching amplifier. Stacked on top of that amplifier are two common-gate stages each comprising a field effect transistor M₂ or M₃ to increase the output impedance. The topmost common-gate stage transistor M₃ improves reverse isolation by providing a high output impedance and thereby isolating the load (represented by inductor L and capacitor C) from the common-source amplifier stage M₁. Note that both common-gate stages M₂ and M₃ are always-ON. These are not arranged to be switchable. The output RFₒ of the amplifier 400 is taken from above the tertiary winding T_{1,t} such that the tertiary winding T_{1,t} lies between the output RFₒ and the drain of M₁.

FIG. 5 shows an embodiment of the invention using an amplifier set up similar to that of FIG. 4, but with the addition of a second circuit branch as shown in FIG. 2 and FIGS. 3a-3d. The embodiment of FIG. 5 implements the first circuit branch 542 with the field effect transistor M₂ as the first switching element 543 and the field effect transistor M₃ as the first buffer element 544. Both M₂ and M₃ are arranged in common-gate configuration. Switching of M₂ is controllable via control signal ϕ₂ generated by controller 548. The drain of M₃ (the first buffer element 544) is connected to the load, represented by inductor L and capacitor C. This is also the output RFₒ of the receiver which passes the amplified signal on to further processing such as an ADC, DSP, etc.

The second circuit branch 545 is implemented with the field effect transistor M₄ as the second switching element 546 and the field effect transistor M₅ as the second buffer element 547. Both M₄ and M₅ are arranged in common-gate configuration. Switching of M₄ is controllable via control signal ϕ₁ generated by controller 548. The drain of M₅ (the second buffer element 547) is connected to the signal ground node 560, which in this case is the supply rail V_{DD} (although any signal ground node can be used to dissipate the signal).

The first buffer element 544 and the second buffer element 547 (i.e., M₃ and M₅) are both in an always-on configuration, with the transistor gates connected to V_{DD}. The first switching element 543 and the second switching element 546 (i.e., M₂ and M₄) are controlled by controller 548 so as to switch the respective circuit branch 542, 545 ON or OFF.

The transistors M₂ and M₄ in FIG. 5 are both low-threshold voltage transistors (LVT) which cannot be fully switched off. Even when 0 V bias is applied to the gate, these transistors will still allow current to pass through the drain-source path at a mere fraction of the normal level (for example at −20 dB, although the amount of leakage can be varied according to design requirements). Ordinarily, this leakage characteristic would be a drawback of the transistor, but in this arrangement, it is being used for a benefit. When ϕ₁ is ON and ϕ₂ is OFF, the signal at the source of M₁ will be split between the first circuit branch 542 and the second circuit branch 545 with a small fraction of the current flowing along the first circuit branch 542 and the remaining fraction flowing along the second circuit branch 545. This mode of operation can be used while the transmitter (not shown in FIG. 5, but may be located upstream of the amplifier 541, e.g., as shown in FIG. 1a or 1b) is generating a strong signal for transmission or when receiving a strong pulse from the antenna. During this time, the strong signal from the transmitter is amplified by amplifier 541 but is then mostly diverted to the signal ground node 560 (in this case the V_{DD} rail) while the remainder leaks through M₂ on the first circuit branch 542. The signal from the transmitter (and also from the antenna) that reaches the load via the first circuit branch 542 is attenuated (<0 dB gain) which is good for protecting the processing circuitry from the strong transmit signal. However, a strong reflection signal (which will be lower in amplitude than the transmit signal) can also be received via this route while the transmitter is ON and transmitting. The strong receive signal will also be attenuated by virtue of the leakage being small, but because the receive signal is still relatively strong it can still be processed and extracted by suitable processing. Thus, pseudo-full-duplex operation can be achieved by receiving at the same time as transmitting.

When the transmitter is not active, the controller 548 switches the first circuit branch 542 ON and the second circuit branch 545 OFF via control signals ϕ₂ and ϕ₁, respectively. First switching element 543 is turned ON and conducts the output from amplifier 541 (from the source of M₁) to the load and RFₒ. Second switching element 546 is turned OFF and minimizes the current diverted to ground. However, as second switching element 546 is also a low-threshold voltage transistor (LVT) it is also slightly leaky such that a small fraction of the current is still diverted to the signal ground node 560. This reduces the overall gain as it reduces the amount of current reaching RFₒ. This loss could be eliminated by having M₄ be a standard threshold voltage transistor (no leakage), but there is a benefit to having M₂ and M₄ having the same characteristics, namely that the amplifier 541 sees the same loading conditions regardless of which circuit branch (first circuit branch 542 or second circuit branch 545) is ON and which is OFF. For the same reason, the first and second buffer elements 544, 547 (i.e., M₃ and M₅) also ideally have the same characteristics.

It will be appreciated that the first and/or second switching elements can be any type of low-threshold voltage transistor, including ultra-low threshold voltage transistors (ULVT) which have higher leakage and extreme-low threshold voltage transistors (ELVT) which have even higher leakage.

When operated in full-duplex (pseudo-full-duplex) mode, i.e., with ϕ₁ ON and ϕ₂ OFF, the forward transmission coefficient, S₂₁ is less zero (S₂₁<0 dB), representing an attenuation of the signal. When operated in receive mode, i.e., with ϕ₁ OFF and ϕ₂ ON, the forward transmission coefficient, S₂₁ is much greater than zero (S₂₁>>0 dB), representing a signal gain.

As has been discussed above, the controller 548 can also use control signals ϕ₂ and ϕ₁ to switch ON both the first circuit branch 542 and the second circuit branch 545 so as to split the current from amplifier 541 (i.e., from the source of M₁) between the two branches. As the two branches are identical in this embodiment (M₂ and M₄ have the same characteristics and M₃ and M₅ have the same characteristics), the current will be split 50:50 such that the gain at the output, RFₒ is halved by this approach (i.e., 6 dB lower). This can help to attenuate a particularly strong receive signal that might saturate the processing circuitry, even in normal receive mode (i.e., when the transmitter is not transmitting and when leakage mode is not required).

FIG. 6 shows the same arrangement as in FIG. 5 except that the signal ground node is different. Instead of the second circuit branch 545 diverting the signal to the supply rail V_{DD}, instead the signal is diverted to an AC ground formed by a capacitor C_{inf} connected to ground. The advantage of this arrangement is to avoid polluting the supply rail with any large swing signal generated by the transmitter. Some components such as an ADC can be quite sensitive to fluctuations in the supply rail and therefore in such situations it may be preferable to divert the unwanted signal away from the supply rail instead.

FIG. 7 is similar to the arrangement of FIG. 5, except that the amplifier 741 is arranged in a common-gate configuration instead of a common-source configuration. The transistor M₁ still operates in conjunction with the three windings T_{1,p}, T_{1,s} and Tit of a trifilar transformer with the primary winding T_{1,p} coupled to the secondary winding T_{1,s} and with the primary winding T_{1,p} coupled to tertiary winding T_{1,t}, but with the secondary winding T_{1,s} not coupled to the tertiary winding T_{1,t} so as to ensure stability and gain of the amplifier. The input RFᵢ is provided at the source of M₁ rather than at the gate as in FIG. 5. The amplifier 741 still functions as an impedance matching amplifier as in FIG. 5. Functionality of this circuit is otherwise as described above in relation to FIG. 5. It will be appreciated that the modification to signal ground that is shown in FIG. 6 may equally be applied to the circuit of FIG. 7.

FIGS. 8a-d show various waveforms that are present in the system during operation. FIG. 8a shows the transmit pulse at the antenna, i.e., the transmit pulse generated by the transmitter 30, after it has passed through the filter 20, referring to the arrangement of FIG. 1a (i.e., attenuated by insertion loss). The transmit pulse has a main body 801 and a low amplitude tail 802. FIG. 8b shows the transmitted pulse as generated by the transmitter 30, without having passed through the filter 20 (and hence of slightly different shape and higher peak amplitude). FIG. 8c shows the pulse at the output of the low-noise amplifier, i.e., showing the effect of the leakage current in attenuating the transmit pulse. FIG. 8d shows the ϕ₁ and ϕ₂ control signals 803, 804. FIGS. 8a and 8c also show vertical lines showing the timing of the rising edge 803 of ϕ₁ (which is a falling edge of ϕ₂) and the subsequent rising edge 804 of ϕ₂ (which is a falling edge of ϕ₁). As can be seen in FIG. 8c, when ϕ₁ is high (ON), i.e. between the vertical lines 803, 804, the output of the low noise amplifier is an attenuated version of the transmit pulse main body 801. This signal is only present due to the leakage current through the first circuit branch (e.g., 542 of FIG. 5) which is in the OFF state. The rest of the amplified transmit signal is diverted to ground via the second circuit branch (e.g., 545 of FIG. 5) which is in the ON state. To the right of vertical line 804, the amplifier is back in amplification mode (first circuit branch is ON and second circuit branch is OFF) and therefore now amplifies the tail 802. As can be seen, the amplifier has switched from an attenuation mode (gain <0 dB) in the region vertical lines 803 and 804 when it is in leakage mode to a high gain mode (gain >>0 dB) in the region to the right of vertical line 804. Any receive signal that is received during these modes of operation therefore still reaches the downstream processing (e.g. ADC and DSP) and can thus be detected even during a transmit pulse, while at the same time ensuring that the transmit pulse is attenuated to a level at which it will not saturate or damage the downstream components during transmit mode. Therefore, the transceiver is working in a pseudo-full-duplex mode. When the transmit pulse is not being transmitted, full receive gain is applied for maximum detection and range.

An important benefit of the embodiments described above is that the frequency response of the receiver does not change when the receiver switches from full receive mode (first circuit branch ON) to leakage mode (first circuit branch OFF) as the first buffer element ensures isolation of the load from the amplifier.

FIG. 9 shows a pulsed (or impulse) radar 900 which comprises a module 960 on which is mounted an antenna 910 and a semiconductor chip 950. The antenna 910 connects to the semiconductor chip 950 via an antenna interface 915. The semiconductor chip 950 contains a filter 920, a transmitter 930 and an amplifier 940 which may be circuits as described above and shown in the preceding figures. In this embodiment the antenna 910, antenna interface 915, filter 920, transmitter 930 and amplifier 940 are all differential. However, a single-ended implementation is also viable by simply implementing one half of the differential circuit.

It will be appreciated that variations and modifications of the above circuits may be made without departing from the scope of the appended claims.

1. A transceiver circuit for transmitting and receiving via a single antenna interface, the transceiver circuit comprising:
a transmitter arranged to send a transmit signal to the antenna interface; and
a receiver, having an input and an output, the input arranged to receive a receive signal from the antenna interface;
wherein the receiver comprises:
a first circuit branch arranged to selectively connect the receiver input to the receiver output; and
a second circuit branch arranged to selectively connect the receiver input to a signal ground node.

2. A transceiver circuit as claimed in claim 1, wherein the first circuit branch is switchable between an ON state and an OFF state and wherein in the ON state the first circuit branch connects the receiver input to the receiver output; and
wherein the second circuit branch is switchable between an ON state and an OFF state and wherein in the ON state the second circuit branch connects the receiver input to the signal ground node.

3. A transceiver circuit as claimed in claim 2, wherein the first circuit branch is arranged such that in the OFF state it passes a leakage current from the receiver input to the receiver output.

4. A transceiver circuit is claimed in claim 3, wherein in the OFF state the first circuit branch has an insertion loss of up to 20 dB, optionally up to 15 dB, optionally up to 10 dB.

5. A transceiver circuit as claimed in claim 3, wherein the first circuit branch comprises a first switchable element, wherein the first switchable element is arranged to switch the first circuit branch between the ON state and the OFF state.

6. A transceiver circuit as claimed in claim 5, wherein the first switchable element is a low-threshold voltage transistor, optionally an ultra-low threshold voltage transistor, optionally an extreme-low threshold voltage transistor.

7. A transceiver circuit as claimed in claim 5, wherein the first circuit branch comprises a first buffer element in series with the first switchable element.

8. A transceiver circuit as claimed in claim 7, wherein the first buffer element is connected between the first switchable element and the receiver output.

9. A transceiver circuit as claimed in claim 7, wherein the first buffer element is a low-threshold voltage transistor, optionally an ultra-low threshold voltage transistor, optionally an extreme-low threshold voltage transistor.

10. A transceiver circuit as claimed in claim 7, wherein the first switchable element and the first buffer element each comprise transistors in a common-gate arrangement.

11. A transceiver circuit as claimed in claim 2, wherein the second circuit branch is arranged such that in the OFF state it passes a leakage current from the receiver input to the signal ground node.

12. A transceiver circuit is claimed in claim 11, wherein in the OFF state the second circuit branch has an insertion loss of up to 20 dB, optionally up to 15 dB, optionally up to 10 dB.

13. A transceiver circuit as claimed in claim 11, wherein the second circuit branch comprises a second switchable element, wherein the second switchable element is arranged to switch the second circuit branch between the ON state and the OFF state.

14. A transceiver circuit as claimed in claim 13, wherein the second switchable element is a low-threshold voltage transistor, optionally an ultra-low threshold voltage transistor, optionally an extreme-low threshold voltage transistor.

15. A transceiver circuit as claimed in claim 5, wherein the second switchable element is identical to the first switchable element.

16. A transceiver circuit as claimed in claim 13, wherein the second circuit branch comprises a second buffer element in series with the second switchable element.

17. A transceiver circuit as claimed in claim 16, wherein the second buffer element is connected between the second switchable element and the signal ground node.

18. A transceiver circuit as claimed in claim 16, wherein the second buffer element is a low-threshold voltage transistor, optionally an ultra-low threshold voltage transistor, optionally an extreme-low threshold voltage transistor.

19. A transceiver circuit as claimed in claim 16, wherein the second switchable element and the second buffer element each comprise transistors in a common-gate arrangement.

20. A transceiver circuit as claimed in claim 16, wherein the second buffer element is identical to the first buffer element.

21. A transceiver circuit as claimed in claim 1, further comprising a controller;
wherein the controller is arranged to operate in at least a transmit mode and a receive mode;
wherein in the receive mode, the controller controls the first circuit branch to connect the receiver input to the receiver output; and
wherein in the transmit mode, the controller controls the second circuit branch to connect the receiver input to the signal ground node.

22. A transceiver circuit as claimed in claim 21,
wherein in the receive mode, the controller controls the second circuit branch to disconnect the receiver input from the signal ground node; and
wherein in the transmit mode, the controller controls the first circuit branch to disconnect the receiver input from the receiver output.

23. A transceiver circuit as claimed in claim 1, wherein the receiver comprises an impedance matching amplifier arranged to receive the receive signal from the antenna interface and arranged to output an amplified signal to the first and/or second circuit branches.

24. A transceiver circuit as claimed in claim 23, wherein the impedance matching amplifier comprises a transistor or multiple transistors arranged in a common-gate and/or a common-source arrangement.

25. A transceiver circuit as claimed in claim 23, wherein the impedance matching amplifier comprises a field effect transistor and wherein the impedance matching amplifier further comprises a transformer coupling the signal between the gate and the source of the field effect transistor.

26. A transceiver circuit as claimed in claim 25, wherein the field effect transistor is in common-source arrangement and the impedance matching amplifier comprises a transformer arranged to increase the amplitude of the signal at the gate of the field effect transistor.

27. A transceiver circuit is claimed in claim 26, wherein the transformer is a trifilar transformer with a primary winding connected to the source, a secondary winding connected between the gate and signal ground and a tertiary winding connected between the secondary winding and the gate, wherein the primary winding and the secondary winding are coupled in inverting relationship, wherein the secondary winding and the tertiary winding are coupled to increase voltage at the gate, and wherein there is substantially no coupling between the primary winding and the tertiary winding.

28. A transceiver circuit as claimed in claim 25, wherein the field effect transistor is in common-gate arrangement and the impedance matching amplifier comprises a transformer coupling the signal between the source and the drain of the field effect transistor.

29. A transceiver circuit as claimed in claim 28, wherein the transformer is a trifilar transformer with a primary winding connected to the source, a secondary winding connected to the gate and a tertiary winding connected to the drain, wherein the primary winding and the secondary winding are coupled in an inverting relationship and wherein the primary winding and the tertiary winding are coupled in non-inverting relationship, and wherein there is substantially no coupling between the secondary winding and the tertiary winding.

30. A transceiver circuit as claimed in claim 1, comprising a controller;
wherein the controller is arranged to operate in a gain control receive mode;
wherein in the gain control receive mode, the controller controls the first circuit branch to connect the receiver input to the receiver output, and the controller controls the second branch to connect the receiver input to the signal ground node.

31. A transceiver circuit as claimed in claim 1, wherein the receiver further comprises:
a third circuit branch arranged to selectively connect the receiver input to a signal ground node.

32. A transceiver circuit as claimed in claim 31, wherein the second and third circuit branches have different current drawing strengths.

33. A transceiver comprising:
a transmitter circuit,
an antenna,
a transceiver circuit as claimed in claim 1.

34. A transceiver as claimed in claim 33, wherein the transmitter circuit comprises an impulse or pulse generator.

35. A pulsed radar comprising a transceiver as claimed in claim 34.

36. A method of duplex operation of a transceiver circuit via a single antenna interface, wherein the transceiver circuit comprises:
a transmitter arranged to send a transmit signal to the antenna interface; and
a receiver, having an input and an output, the input arranged to receive a receive signal from the antenna interface;
wherein the receiver comprises:
a first circuit branch arranged to selectively connect the receiver input to the receiver output; and
a second circuit branch arranged to selectively connect the receiver input to a signal ground node;
wherein the method comprises:
while the transmitter is transmitting, operating the second circuit branch to connect the receiver input to the signal ground node and operating the first circuit branch to operate in a leakage mode in which the receiver input is disconnected from the receiver output apart from a leakage current that still passes from the receiver input to the receiver output.

37. A method as claimed in claim 36, further comprising:
While the transmitter is not transmitting, operating the second circuit branch to disconnect the receiver input from the signal ground node and operating the first circuit branch to connect the receiver input to the receiver output.
